(19) United States
(12) Patent Application Publication
(10) Pub. No.: US 2007/0063319 A1
(43) Pub. Date: Mar. 22, 2007

(54) Film stack and method for fabricating the same

(76) Inventors: Bohumil Lojek, Colorado Springs, CO (US); Gary Frazier, Colorado Springs, CO (US)

Correspondence Address: SCHNECK & SCHNECK, P.O. BOX 2-E, SAN JOSE, CA, 95109-0005, US

(21) Appl. No.: 11/229,796

(22) Filed: Sep. 19, 2005

(51) Int. Cl. H01L 21/76

(52) U.S. Cl. 257/647; 438/424; 438/585

(57) ABSTRACT

A film stack and a method for fabricating the same. In one embodiment, a film stack comprises a semiconductor substrate with the following layers: a first layer of oxide over the substrate; a first layer of polycrystalline silicon over the first layer of oxide; a second layer of oxide over the first layer of polycrystalline silicon; a second layer of polycrystalline silicon over the second layer of oxide; a third layer of oxide over the second layer of polycrystalline silicon; and a layer of nitride over the third layer of oxide. The second layer of polycrystalline silicon and the third layer of oxide reduce the formation of bird's beaks after liner oxidation of a trench formed in the film stack. The reduced bird's beaks prevent unwanted residual strings of the first layer of polycrystalline silicon remaining after subsequent processing of the film stack.

### TECHNICAL FIELD

This invention relates to a film stack that may be used in fabricating semiconductor devices and a method for fabricating the film stack.

### BACKGROUND ART

Silicon dioxide regions in integrated chips which isolate circuit elements from each other are generally formed in one of two ways. A Local Oxidation of Silicon (“LOCOS”) process forms the silicon dioxide regions by thermally oxidizing a portion of the chip surface; a Shallow Trench Isolation (“STI”) process forms the silicon dioxide regions by etching a shallow trench into the silicon substrate and filling the etched area with silicon dioxide.

A drawback with LOCOS is the formation of “birds' beaks,” where oxidant diffuses into the active region of the device structure and may negatively affect the reliability of the device. The bird's beak effect is limited when STI is used; however, as shown below, minor bird's beaks which impact the reliability of the device may still occur.

In FIG. 1, a structure 20 used in the prior art fabrication of non-volatile memory devices has a semiconductor substrate 10, a first dielectric layer 12, such as silicon dioxide, a first semiconductor layer 14, such as polycrystalline silicon (“poly”), a second dielectric layer 16, such as a pad oxide, and a third dielectric layer 18, such as nitride. The first dielectric layer 12 is typically 50-200 Å, the first semiconductor layer 14 is typically 1-1.5 KÅ, the second dielectric layer 16 is typically less than 200 Å, and the third dielectric layer is typically less than 1.5 KÅ. In FIG. 2, trenches 22 are etched into the structure 20 using an STI process, which is well-known in the art.

In FIG. 3, a film of silicon dioxide 24 (so-called “liner oxide”) is thermally grown on the trench 22 walls in a liner oxidation step. A detailed view 30 of the structure 20 after the liner oxidation shows that mini bird's beaks 32, 34 have been formed as a result of the liner oxidation, where the silicon dioxide 24 has consumed corner areas of the first semiconductor layer 14.

These bird's beaks 32, 34 may cause problems in the device built by processing the structure 20. In FIG. 4, a portion of the structure 20 is shown after the trenches are filled with silicon dioxide 36 and after the second 16 and third dielectric 18 layers have been removed. A detailed view 38 shows that the edges of the first semiconductor layer 14 are rounded as a result of the birds' beaks. In FIG. 5, a layer of poly 40 has been deposited to form a floating gate, and the layer of poly 40 has been masked and etched. A detailed view 42 of an area where the etching process took place shows there is an area, or string, of residual poly 44 (corresponding to the rounded edges of the poly layer 14 shown in FIG. 4) which is difficult to remove during a subsequent dry etching process. The liner oxide 24 is not etched when semiconductor or poly layer 14 is etched; therefore, liner oxide 24 acts as a mask to residual poly 44, which remains after the layer of poly 14 is etched. This residual poly string 44 causes problems in the area between devices as it can lead to shorts between the gates of two neighbor cells because there is insufficient electrical insulation between the devices. It would be desirable to develop a film stack used in fabricating semiconductor structures that minimized formation of birds, beaks, thereby preventing unwanted residual poly strings 44 remaining after certain processing steps.

### SUMMARY OF THE INVENTION

In one embodiment, a film stack comprises a semiconductor substrate with the following layers: a first dielectric layer over the substrate; a first semiconductor layer over the first dielectric layer; a second dielectric layer over the first semiconductor layer; a second semiconductor layer over the second dielectric layer; a third dielectric layer over the second semiconductor layer; and a fourth dielectric layer over the third dielectric layer. The second semiconductor layer and the third dielectric layer reduce formation of a bird's beak following oxidation of a trench structure formed in the film stack during subsequent processing. Reducing formation of a bird's beak prevents an unwanted residual string of the first semiconductor layer remaining after subsequent processing of the film stack.

In another embodiment, a film stack comprises a semiconductor substrate with the following layers: a first layer of oxide over the substrate; a first layer of polycrystalline silicon over the first layer of oxide; a second layer of oxide over the first layer of polycrystalline silicon; a second layer of polycrystalline silicon over the second layer of oxide; a third layer of oxide over the second layer of polycrystalline silicon; and a layer of nitride over the third layer of oxide. The second polycrystalline silicon layer and the third oxide layer reduce formation of a bird's beak following oxidation of a trench structure formed in the film stack during subsequent processing. Reducing formation of a bird's beak prevents an unwanted residual string of the first layer of polycrystalline silicon remaining after subsequent processing of the film stack.

In yet another embodiment, a method for fabricating a structure comprises forming a stacked structure which includes a semiconductor substrate, a first layer of oxide over the substrate, a first layer of polycrystalline silicon over the first layer of oxide, a second layer of oxide over the first layer of polycrystalline silicon, a second layer of polycrystalline silicon over the second layer of oxide, a third layer of oxide over the second layer of polycrystalline silicon, and a layer of nitride over the third layer of oxide. At least one trench structure in the stacked structure is defined. The trench structure is then oxidized. The second layer of polycrystalline silicon and the third layer of oxide reduce formation of a bird's beak following oxidation of a trench structure formed in the film stack during subsequent processing. The reduced bird's beak prevents an unwanted residual string of the first layer of polycrystalline silicon remaining after subsequent processing of the film stack.

### BRIEF DESCRIPTION OF THE DRAWINGS

FIG. 1 is a cross-section of a film stack at a starting point of a process known in the prior art.

FIGS. 2-5 are cross-sections of semiconductor structures at selected processing stages according to the prior art.

FIG. 6 is a cross-section of a film stack at a starting point of an embodiment of the invention.

FIGS. 7-10 are cross-sections of semiconductor structures at selected processing stages according to an embodiment of the invention.

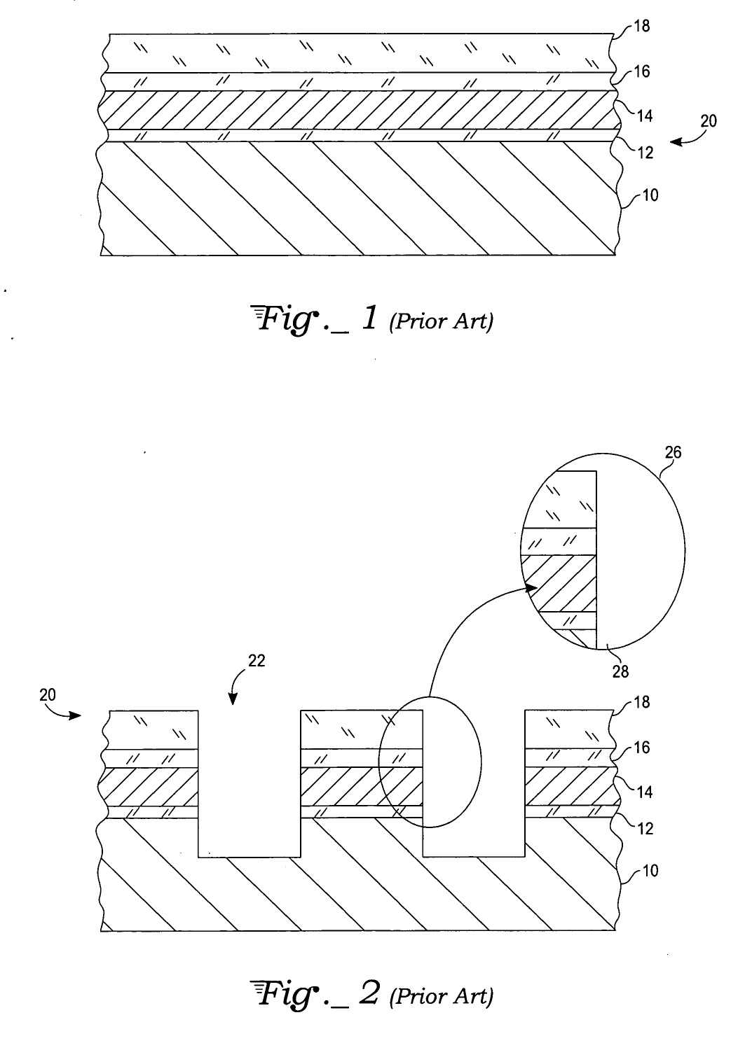

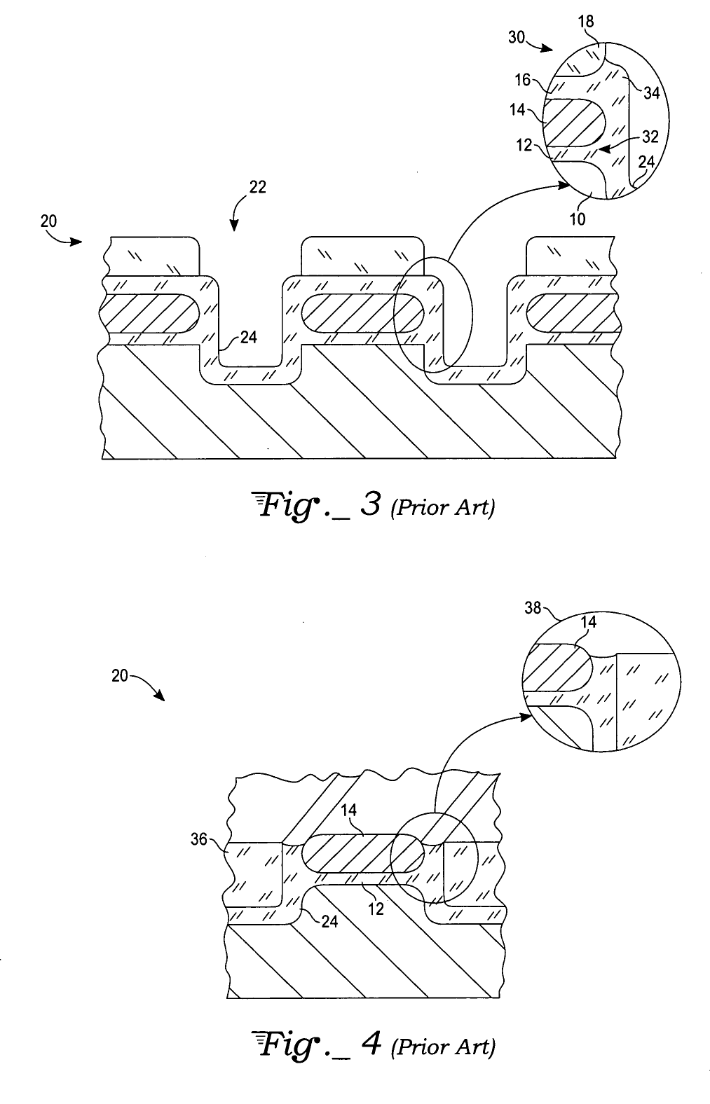

### DETAILED DESCRIPTION

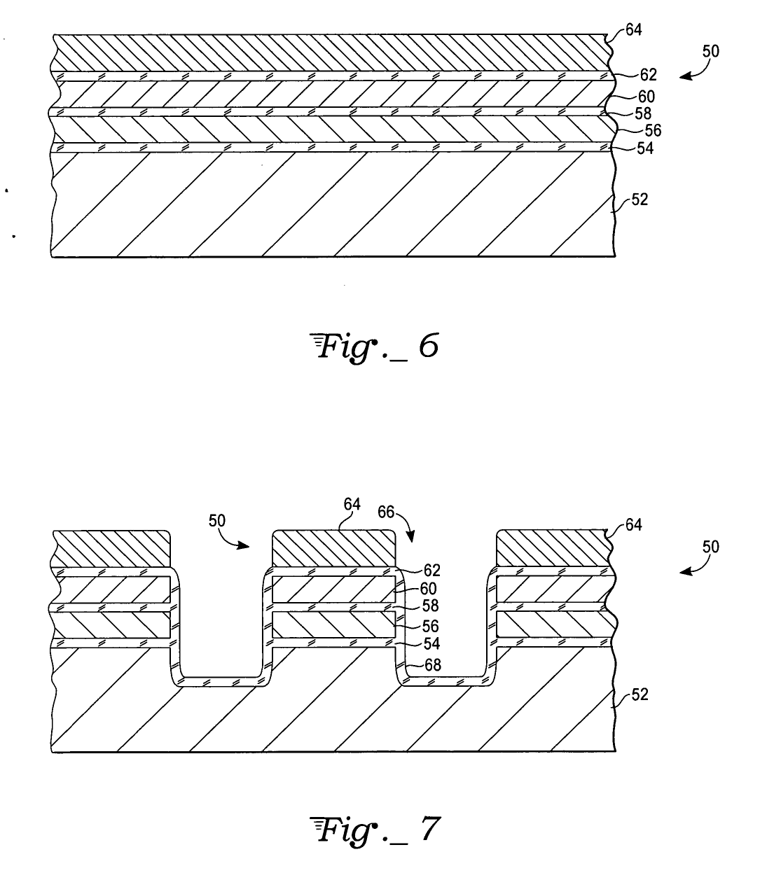

In FIG. 6, one exemplary embodiment of a film stack 50 that may be used to fabricate semiconductor structures and devices without the formation of a bird's beak is shown. A semiconductor substrate 52, for example p-type silicon, is provided. The substrate 52 is prepared in the usual way, for example, by a pre-oxidation cleaning procedure. A skilled artisan will recognize that embodiments described herein are readily amenable to use with other substrate types as well. For example, the substrate 52 could be another elemental type of semiconductor (e.g., germanium). Further, the substrate 52 may be comprised of a non-semiconducting material, such as a quartz reticle. A first dielectric layer 54, for example, an oxide, is deposited on the substrate. The targeted thickness of the first dielectric layer 54 may be between 30-200 Å, typically about 100 Å. A first semiconductor layer 56, for example polycrystalline silicon, is then deposited or otherwise formed over the dielectric layer. The first semiconductor layer 56 may have a target thickness ranging between 150-500 Å, typically about 300 Å. A thin dielectric layer 58, such as a silicon dioxide layer that is about 20-50 Å thick, is deposited or thermally grown on the first semiconductor layer 56. A second semiconductor layer 60, for instance polycrystalline silicon, having a target thickness between 150-500 Å, typically 300 Å, is deposited on the thin dielectric layer 58. A third dielectric layer 62, for instance a pad oxide, having a target thickness between 50-200 Å is deposited or grown on the second semiconductor layer 60. A fourth dielectric layer 64, for instance, nitride, having a target thickness between 500 Å-1.5 KÅ is deposited on the third dielectric layer 62. In the following discussion, the first dielectric layer 54 will be referred to as the first oxide layer, the first semiconductor layer 56 will be referred to as the first poly layer, etc., consistent with the specific exemplary materials discussed above. This is for exemplary purposes for a particular embodiment and those skilled in the art will appreciate other dielectric and semiconductor, etc., materials other than those specifically mentioned here may be used.

At least one trench is then etched in the film stack 50 using well-known STI methods. In FIG. 7, the trench 66 is covered with a thin film of oxide 68 in a liner oxidation process. Due to the presence of the second poly layer 60 and the pad oxide layer 62, it can be seen formation of bird's beaks is minimized (by up to 90%) and that the edges of the poly layers 56, 60 are not rounded as the edges of the poly layer were after liner oxidation in the prior art process shown in FIG. 3, above. Instead, the poly edges 56, 60 are rather flat.

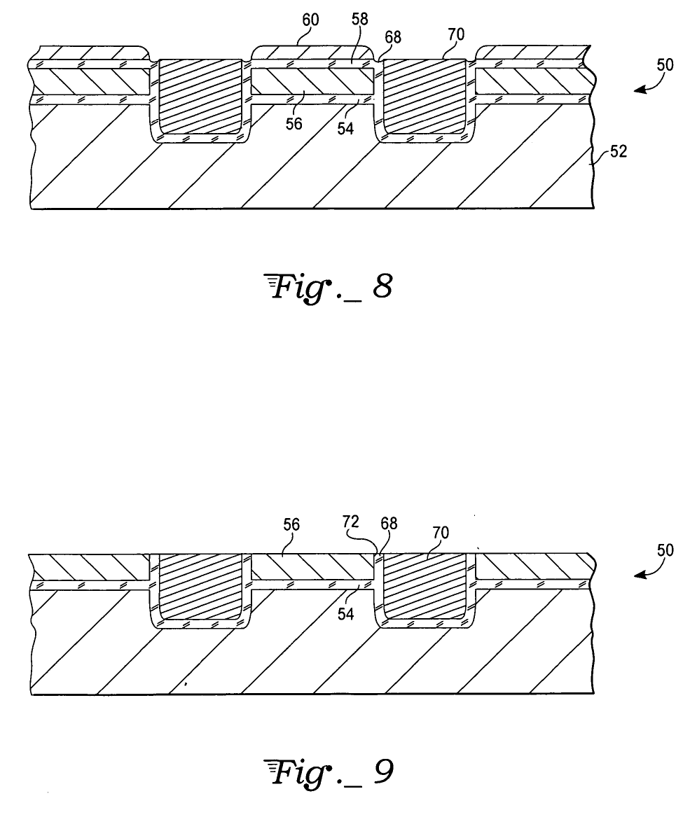

The trench is then filled with silicon dioxide 70. The nitride layer 64 is removed by chemical mechanical planarization (“CMP”). (In other embodiments, this layer may be removed by another process, such as etching.) The pad oxide layer 62 is removed by a buffered oxide etch (“BOE”). In FIG. 8, a resulting structure 50 is shown.

Poly layer 60 is then removed by etching. Oxide layer 58 is removed by BOE. In FIG. 9, it can be seen that in the resulting structure 50, the edge of poly layer 56 is flat, or straight, rather than rounded.

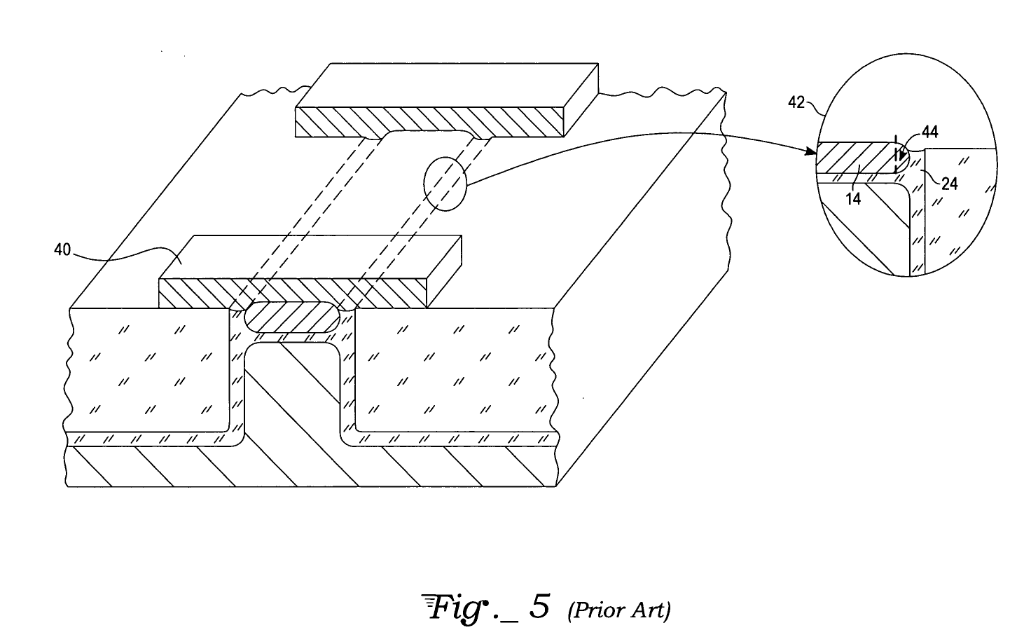

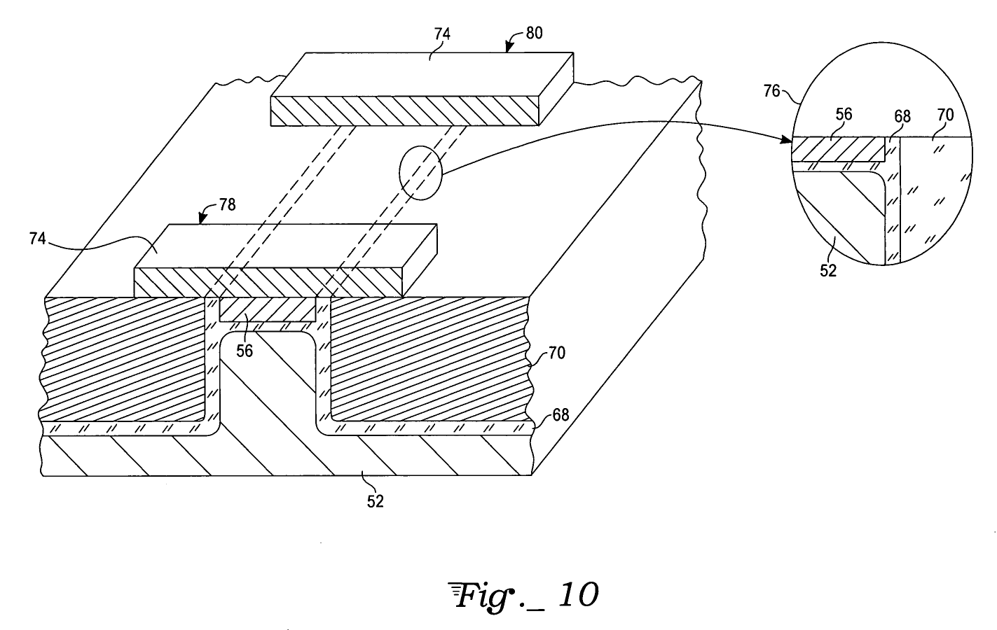

In FIG. 10, a continuous layer of poly 74 has been deposited to act as a floating gate, a mask applied, and the unprotected poly layer 74 is etched. As shown in detailed view 76, the edge of poly layer 56 is flat, in contrast to the rounded edge of poly layer 14 shown in FIG. 5. Returning to FIG. 10 this poly layer 56 between neighboring devices 78, 80 may be removed by a dry etching process without leaving residual poly stringers.

Electrical data show that devices fabricated using the processes described above have no shorts between the gates of neighboring cells. In contrast, randomly distributed shorts occur in approximately ten to fifteen percent of the area of the wafer when prior art processes are used.

The film stack shown in FIG. 6 and semiconductor structures shown in FIGS. 7-9 may be used to fabricate numerous semiconductor devices. While the preceding description has described specific embodiments, it will be evident to a skilled artisan that various changes and modifications can be made to these embodiments (for instance different elemental types of semiconductor or compound semiconductor (e.g., a III-V or II-VI material) may be employed). The specification and drawings, therefore, are to be regarded in an illustrative rather than a restrictive sense.

What is claimed is:

1. A film stack comprising:
a) a semiconductor substrate;
b) a first dielectric layer over the substrate;
c) a first semiconductor layer over the first dielectric layer;
d) a second dielectric layer over the first semiconductor layer;
e) a second semiconductor layer over the second dielectric layer;
f) a third dielectric layer over the second semiconductor layer, the second semiconductor layer and the third dielectric layer reducing formation of a bird's beak following oxidation of a trench structure formed in the film stack during subsequent processing of the film stack, the reduced bird's beak preventing an unwanted residual string of the first semiconductor layer remaining after subsequent processing of the film stack; and
g) a fourth dielectric layer over the third dielectric layer.

2. The film stack of claim 1 wherein the first dielectric layer is an oxide.

3. The film stack of claim 1 wherein the first semiconductor layer is polycrystalline silicon.

4. The film stack of claim 1 wherein the second dielectric layer is an oxide.

5. The film stack of claim 1 wherein the second semiconductor layer is an oxide.

6. The film stack of claim 1 wherein the third dielectric layer is an oxide.

7. The film stack of claim 1 wherein the fourth dielectric layer is nitride.

8. A film stack comprising:
a) a semiconductor substrate;
b) a first layer of oxide over the substrate;
c) a first layer of polycrystalline silicon over the first layer of oxide;
d) a second layer of oxide over the first layer of polycrystalline silicon;
e) a second layer of polycrystalline silicon over the second layer of oxide;
f) a third layer of oxide over the second layer of polycrystalline silicon, the second polycrystalline layer and the third layer of oxide reducing formation of a bird's beak following oxidation of a trench structure formed in the film stack during subsequent processing of the film stack, the reduced bird's beak preventing an unwanted residual string of the first layer of polycrystalline silicon remaining after subsequent processing of the film stack; and
g) a layer of nitride over the third layer of oxide.

9. A method for fabricating a structure comprising:
a) forming a stacked structure including:
i) a semiconductor substrate;
ii) a first layer of oxide over the substrate;
iii) a first layer of polycrystalline silicon over the first layer of oxide;
iv) a second layer of oxide over the first layer of polycrystalline silicon;
v) a second layer of polycrystalline silicon over the second layer of oxide;
vi) a third layer of oxide over the second layer of polycrystalline silicon, the polycrystalline silicon layer and the third layer of oxide reducing formation of a bird's beak following oxidation of a trench structure formed in the film stack during subsequent processing of the film stack, the reduced bird's beak preventing an unwanted residual string of the first layer of polycrystalline silicon remaining after subsequent processing of the film stack; and
vii) a layer of nitride over the third layer of oxide;
b) defining at least one trench structure in the stacked structure; and
c) oxidizing the at least one trench structure.
